(19) United States
(12) Patent Application Publication
(10) Pub. No.: US 2017/0223816 A1
(43) Pub. Date: Aug. 3, 2017

(54) FLEXIBLE PRINTED WIRING BOARD, ELECTRONIC DEVICE HAVING FLEXIBLE PRINTED WIRING BOARD, AND METHOD FOR MANUFACTURING ELECTRONIC DEVICE HAVING FLEXIBLE PRINTED WIRING BOARD

(71) Applicant: IBIDEN CO., LTD., Ogaki (JP)

(72) Inventors: Takahisa HIRASAWA, Ibi-gun (JP); Kiyotaka TSUKADA, Ibi-gun (JP)

(73) Assignee: IBIDEN CO., LTD., Ogaki (JP)

(21) Appl. No.: 15/421,618

(22) Filed: Feb. 1, 2017

(30) Foreign Application Priority Data
Feb. 1, 2016 (JP) 2016-017251
Jun. 14, 2016 (JP) 2016-117907

(51) Int. Cl. H05K 1/02; H05K 3/32; H05K 1/14; H05K 1/09

(52) U.S. Cl. CPC H05K 1/021; H05K 1/09; H05K 3/328; H05K 1/147

(57) ABSTRACT

A flexible printed wiring board includes a flexible insulating layer, a conductor layer formed on a surface of the flexible insulating layer, and a metal block including a welding base material and positioned such that the metal block is penetrating through the flexible insulating layer and the conductor layer.

### CROSS-REFERENCE TO RELATED APPLICATIONS

The present application is based upon and claims the benefit of priority to Japanese Patent Application s No. 2016-017251, filed Feb. 1, 2016 and No. 2016-117907, filed Jun. 14, 2016, the entire contents of which are incorporated herein by reference.

### BACKGROUND OF THE INVENTION

Field of the Invention

The present invention relates to a flexible printed wiring board, an electronic device having the flexible printed wiring board, and a method for manufacturing the electronic device having the flexible printed wiring board.

Description of Background Art

Japanese Patent Laid-Open Publication No. 2002-25653 describes that an end of a metal connection terminal having a bonding end is arranged on a conductor pattern of a flexible substrate, and resistance welding is performed between the end of the connection terminal and the conductor pattern of the flexible substrate. The entire contents of this publication are incorporated herein by reference.

### SUMMARY OF THE INVENTION

According to one aspect of the present invention, a flexible printed wiring board includes a flexible insulating layer, a conductor layer formed on a surface of the flexible insulating layer, and a metal block including a welding base material and positioned such that the metal block is penetrating through the flexible insulating layer and the conductor layer.

According to another aspect of the present invention, a method for manufacturing an electronic device includes preparing a flexible printed wiring board including a flexible insulating layer, a conductor layer formed on a surface of the flexible insulating layer, and a metal block including a welding base material and positioned such that the metal block is penetrating through the flexible insulating layer and the conductor layer, and bring a welding tool of a resistance welding machine into contact with a first surface of the metal block in the flexible printed wiring board such that a second surface of the metal block in in the flexible printed wiring board is directly bonded to a metal connection terminal of a structural member by resistance welding.

### BRIEF DESCRIPTION OF THE DRAWINGS

A more complete appreciation of the invention and many of the attendant advantages thereof will be readily obtained as the same becomes better understood by reference to the following detailed description when considered in connection with the accompanying drawings, wherein:

FIG. 1 is a cross-sectional view schematically illustrating an example of a flexible printed wiring board according to an embodiment of the present invention;

FIG. 2 is a top view schematically illustrating an example of an electronic device according to an embodiment of the present invention;

FIG. 3 is a cross-sectional view along a B-B′ line in FIG. 2 and schematically illustrates the example of an electronic device according to an embodiment of the present invention;

FIG. 4 is a cross-sectional view schematically illustrating another example of an electronic device according to an embodiment of the present invention;

FIG. 5A-5D are process diagrams schematically illustrating an example of a method for manufacturing the flexible printed wiring board according to an embodiment of the present invention;

FIG. 6 is a cross-sectional view schematically illustrating a state in which a welding tool of a resistance welding machine is brought into contact with one surface of a metal part of a flexible printed wiring board and resistance welding is performed; and

FIG. 7 is a cross-sectional view schematically illustrating a state in which a welding tool of a resistance welding machine is brought into contact with one surface of a metal part of a flexible printed wiring board and resistance welding is performed.

### DETAILED DESCRIPTION OF THE EMBODIMENTS

The embodiments will now be described with reference to the accompanying drawings, wherein like reference numerals designate corresponding or identical elements throughout the various drawings.

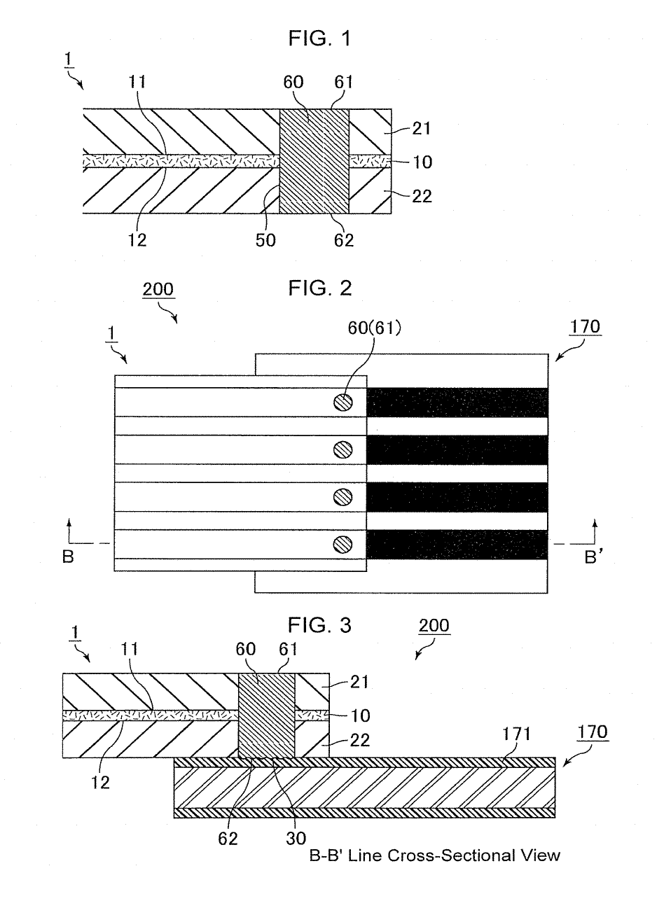

FIG. 1 is a cross-sectional view schematically illustrating an example of a flexible printed wiring board according to an embodiment of the present invention.

As illustrated in FIG. 1, a flexible printed wiring board 1 includes a flexible insulating layer 10 that has a first main surface 11 and a second main surface 12 (that is on an opposite side of the first main surface 11), a first conductor layer 21 that is formed on the first main surface 11 of the flexible insulating layer 10, and a second conductor layer 22 that is formed on the second main surface 12 of the flexible insulating layer 10. The flexible printed wiring board 1 includes a hole 50 that penetrates the first conductor layer 21, the flexible insulating layer 10 and the second conductor layer 22, and a metal block 60 as a metal part that is inserted into the hole 50.

The flexible insulating layer is preferably formed of an insulating resin. Examples of a material that forms the insulating resin include polyimide, glass epoxy, and the like. Among these, polyimide is preferred. When the insulating resin is polyimide, the insulating resin is both flexible and insulating. Therefore, a shape can be deformed according to an intended use, while sufficient insulation is ensured.

A thickness of the flexible insulating layer is not particularly limited. However, it is preferable that the thickness of the flexible insulating layer be 30-70 μm. When the thickness of the flexible insulating layer is smaller than 30 μm, the flexible insulating layer easily bends. Further, since the flexible insulating layer easily bends, bonding of the flexible insulating layer with a wiring or another member can be easily broken. On the other hand, when the thickness of the flexible insulating layer is larger than 70 μm, when a hole is formed by punching in order to have a metal part, a crack is likely to occur around the hole and reliability may decrease.

A conductor layer is formed on at least one side of the flexible insulating layer. FIG. 1 illustrates an example in which a conductor layer is formed on both sides of the flexible insulating layer.

A material that forms the conductor layer is not particularly limited. However, it is preferable that the material be copper, nickel or the like.

These materials have good electrical conductivity and are suitable as conductors.

Thicknesses of the first conductor layer and the second conductor layer are not particularly limited. However, it is preferable that the first conductor layer and the second conductor layer be each thicker than the flexible insulating layer. Further, it is preferable that the thicknesses of the first conductor layer and the second conductor layer be each 10-300 μm. When the thicknesses of the first conductor layer and the second conductor layer are each smaller than 10 μm, during handling, the conductor layers are easily broken and a failure rate increases. On the other hand, when the thicknesses of the first conductor layer and the second conductor layer are each greater than 300 μm, when the flexible printed wiring board is bent and used, due to the bending, a compressive stress applied from the conductor layers to the flexible printed wiring board is increased and thus the flexible printed wiring board is easily broken.

The metal part penetrates the flexible insulating layer and the conductor layers and is a welding base material. This means that regardless of a form of the metal connection terminal of the other member, the flexible printed wiring board itself has a weldable structure.

A material of the metal part is not particularly limited. However, it is preferable that the material be copper that is excellent in electrical conductivity and thermal conductivity. Further, the metal part is preferably a metal block and more preferably a copper block. It is preferable that the metal part be inserted in a hole that is provided so as to penetrate the flexible printed wiring board. A metal block inserted in the hole becomes a metal part that penetrates the flexible insulating layer and the conductor layers.

The metal block is suitable for flowing a large current, and is suitable for welding to a metal connection terminal as compared to a case of a structure such as a through hole or a bottomed filled via that can be considered as a structure of the metal part.

Different from a filled via that is formed in a through hole through a chemical process such as plating, a metal block does not have voids formed therein and does not have concave or convex portions or the like on a surface thereof. Since there are no voids formed inside a metal block, heat-transfer efficiency of the metal block is not reduced and heat dissipation performance of the metal block can be ensured. Further, the metal block is also preferable in that a conductor volume thereof can be easily increased as compared to a filled via.

Further, a shape of the metal block is not particularly limited. However, it is preferable that the shape of the metal block be a columnar shape having a flat bottom surface (surface). Examples of such a shape include shapes of a circular column, a quadrangular column, a hexagonal column, an octagonal column, and the like.

The metal part is formed from a base material for welding to a metal connection terminal of another member. Specifically, a surface of the metal part is exposed on a main surface of the flexible printed wiring board, and can be used as a weldable weld. It is possible to have an embodiment in which only one of the surfaces of the metal part positioned at one of the two main surfaces of the flexible printed wiring board can be used as a weld. It is also possible to have an embodiment in which the surfaces of the metal part that are respectively positioned at the two main surfaces of the flexible printed wiring board can be used as welds.

Further, it is preferable that the metal part be formed from a base material for resistance welding.

In order to resistively weld the metal part to a metal connection terminal, a welding tool of a resistance welding machine as an electrode is brought into contact with one surface of the metal part, and a metal connection terminal of another member is brought into contact with the other surface of the metal part.

Then, when a current is caused to flow from the welding tool that is in contact with one surface of the metal part, heat is generated between the other surface of the metal part and the metal connection terminal of the other member, and thus resistance welding can be performed.

In a flexible printed wiring board according to an embodiment of the present invention, it is preferable that the metal part have a cross-sectional area of 0.05-3.2 mm². The cross-sectional area of the metal part is an area of the surface of the metal part when the flexible printed wiring board is viewed from above.

When the cross-sectional area of the metal part is 0.05 mm² or more, resistance of the metal part itself is sufficiently small, and thus the metal part can be prevented from being melted by the current that is caused to flow for resistance welding. On the other hand, a large metal part having a cross-sectional area exceeding 3.2 mm² may not usually be required.

Next, an electronic device having a flexible printed wiring board according to an embodiment of the present invention (hereinafter, also referred to as an electronic device according to an embodiment of the present invention or an electronic device) is described.

In an electronic device according to an embodiment of the present invention, the metal part of a flexible printed wiring board according to an embodiment of the present invention and a metal connection terminal of another member are directly bonded.

The other member is not particularly limited as long as it is a member that has a metal connection terminal. Examples of the other member include a rigid substrate, a heat sink, a motherboard, and a light-emitting element (such as an LED chip).

In the following, examples in which the other member in the electronic device is a rigid substrate or a heat sink are described using the drawings.

FIG. 2 is a top view schematically illustrating an example of an electronic device according to an embodiment of the present invention. FIG. 3 is a cross-sectional view along a B-B′ line in FIG. 2 and schematically illustrates the example of the electronic device according to the embodiment of the present invention.

In an electronic device 200 illustrated in FIGS. 2 and 3, the other member is a rigid substrate. The metal block 60 of the flexible printed wiring board 1 and a conductor pattern 171 formed in a rigid substrate 170, which is the other member, are directly bonded to each other by welding. The conductor pattern 171 corresponds to a metal connection terminal. A surface 62 of the metal block 60 is welded to the conductor pattern 171 of the rigid substrate 170 by resistance welding and a weld 30 (portion indicated by a wavy line in FIG. 3) is formed. The entire surface 62 of the metal block 60 becomes the weld 30.

The part of the conductor pattern 171 of the rigid substrate 170 to which the surface 62 of the metal block 60 is welded is not particularly limited.

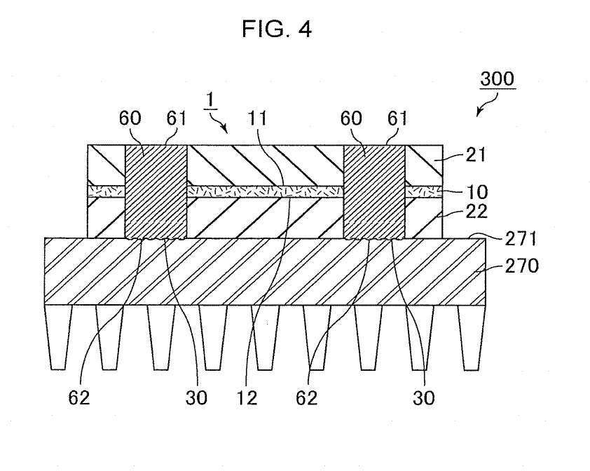

FIG. 4 is a cross-sectional view schematically illustrating another example of an electronic device according to an embodiment of the present invention.

In an electronic device 300 illustrated in FIG. 4, the other member is a heat sink. The metal block 60 of the flexible printed wiring board 1 and a surface 271 of a heat sink 270, which is the other member, are directly bonded to each other by welding. The surface 271 of the heat sink corresponds to a metal connection terminal.

The surface 62 of the metal block 60 is welded to the surface 271 of the heat sink by resistance welding and a weld 30 (portion indicated by a wavy line in FIG. 4) is formed. The entire surface 62 of the metal block 60 becomes the weld 30.

The part of the surface 271 of the heat sink to which the surface 62 of the metal block 60 is welded is not particularly limited. FIG. 4 illustrates a state in which multiple (two) metal blocks are each welded to the heat sink.

A material of the metal connection terminal is not particularly limited as long as the material can be welded to the metal part of the flexible printed wiring board, and is preferably a material that can be welded to copper, which is a preferred material for the metal part of the flexible printed wiring board. For example, copper, stainless steel, nickel, and the like can be adopted.

The term “direct bonding” in an electronic device according to an embodiment of the present invention means that the metal part of the flexible printed wiring board and the metal connection terminal of the other member are bonded to each other without using another member such as a solder. Specifically, it is preferable that the metal part of the flexible printed wiring board and the metal connection terminal of the other member be welded to each other. As the welding, resistance welding or laser welding can be adopted, and resistance welding is preferred.

In the case of resistance welding, the entire interface between the metal part of the flexible printed wiring board and the metal connection terminal of the other member becomes a weld and strength of the welding is increased. On the other hand, in the case of laser welding, of the interface between the metal part of the flexible printed wiring board and the metal connection terminal of the other member, only a portion corresponding to a diameter of a laser beam becomes a weld, and thus the strength of the welding is decreased as compared to the case of resistance welding.

The welds formed by resistance welding and laser welding have different forms. Therefore, it is possible to distinguish whether direct bonding between the metal part of the flexible printed wiring board and the metal connection terminal of the other member is performed by resistance welding or by laser welding.

In the following, a method for manufacturing a flexible printed wiring board according to an embodiment of the present invention and a method for manufacturing the electronic device having a flexible printed wiring board according to an embodiment of the present invention are described.

### Method for Manufacturing Flexible Printed Wiring Board

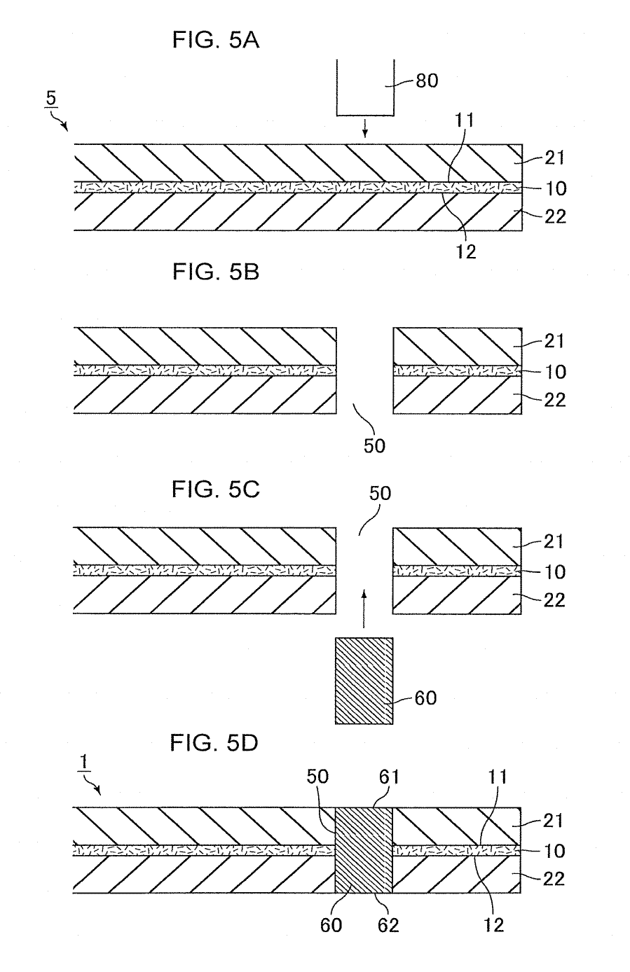

FIG. 5A-5D are process diagrams schematically illustrating an example of a method for manufacturing a flexible printed wiring board according to an embodiment of the present invention.

### (1) Conductor Substrate Preparation Process

First, as a conductor substrate preparation process, a conductor substrate is prepared in which a conductor layer is formed on at least one side of a flexible insulating layer. The conductor layer becomes a first conductor layer and/or a second conductor layer.

FIG. 5A illustrates a process in which a double-sided conductor substrate 5 is prepared in which a first conductor layer 21 is formed on a first main surface 11 of a flexible insulating layer 10 and a second conductor layer 22 is formed on a second main surface 12 of the flexible insulating layer 10, the flexible insulating layer 10 being formed from an insulating resin and having the first main surface 11 and the second main surface 12 that is on an opposite side of the first main surface 11.

Materials that form the flexible insulating layer 10, the first conductor layer 21 and the second conductor layer 22 are the same as those described in the description of the flexible printed wiring board and thus a description thereof is omitted.

### (2) Hole Formation Process

Next, a hole 50 that penetrates the first conductor layer 21, the flexible insulating layer 10 and the second conductor layer 22 is formed.

It is preferable that the hole be formed by punching. FIG. 5A illustrates a state in which a punch 80 that is used in punching is positioned on the first conductor layer 21 side.

FIG. 5B illustrates the double-sided conductor substrate in which the hole 50 is formed.

### (3) Metal Block Insertion Process

Next, by inserting a metal block into the hole, a metal part penetrating the flexible insulating layer and the conductor layers is formed. It is preferable that the insertion of the metal block be performed from the side opposite to the side where punching is performed.

FIG. 5C illustrates an example in which a metal block 60 is inserted into the hole 50 from the second conductor layer 22 side.

Further, when necessary, it is preferable to perform pattern formation with respect to the conductor layers to form necessary wirings. Further, it is preferable to perform coining to improve flatness of surfaces of the metal block.

By the above-described processes, a flexible printed wiring board according to an embodiment of the present invention as shown in FIG. 5D can be manufactured.

Method for Manufacturing Electronic Device having Flexible Printed Wiring Board

A method for manufacturing an electronic device having a flexible printed wiring board according to an embodiment of the present invention includes a process in which a welding tool of a resistance welding machine is brought into contact with one surface of the metal part of a flexible printed wiring board according to an embodiment of the present invention and the other surface of the metal part is directly bonded to a metal connection terminal of another member by resistance welding.

The metal part of a flexible printed wiring board according to an embodiment of the present invention penetrates the flexible insulating layer and the conductor layers. Therefore, by bring the welding tool of the resistance welding machine into contact with one surface of the metal part, a current can be caused to flow toward the other surface of the metal part. When the other surface of the metal part is brought into contact with the metal connection terminal of the other member, heat is generated due to interface resistance between the other surface of the metal part and a surface of the metal connection terminal of the other member. Metals that respectively form the metal part and the metal connection terminal melt due to the heat, and resistance welding is performed. As a result, the other surface of the metal part and the metal connection terminal of the other member are directly bonded to each other by the resistance welding.

Here, it is preferable that a diameter of the metal part be larger than a diameter of the welding tool on a plane on which the metal part and the welding tool are in contact with each other. It is preferable that the entire contact surface of the welding tool enter the surface of the metal part such that the contact surface of the welding tool does not come out from a peripheral edge of the surface of the metal part.

Further, of welding tools of the resistance welding machine, one welding tool is in contact with one surface of the metal part. A position that the other welding tool touches is not particularly limited as long as the position allows the resistance welding to be performed. It is preferable that the other welding tool be brought into contact with a part of the other member.

A method for manufacturing an electronic device having a flexible printed wiring board according to an embodiment of the present invention is described in detail using the drawings.

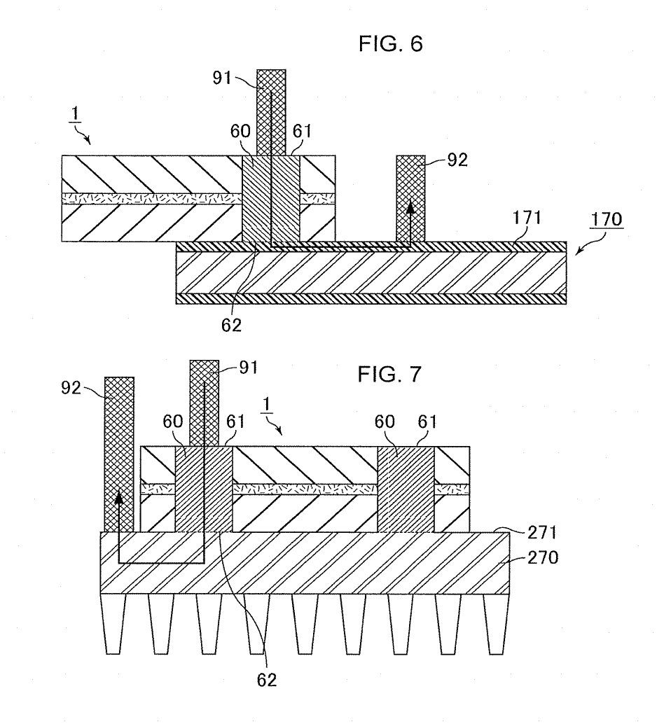

FIGS. 6 and 7 are cross-sectional views schematically illustrating states in each of which a welding tool of a resistance welding machine is brought into contact with one surface of a metal part of a flexible printed wiring board and resistance welding is performed. FIGS. 6 and 7 respectively schematically illustrate states in which resistance welding is performed when the electronic devices illustrated in FIGS. 3 and 4 are manufactured.

In FIG. 6, a welding tool 91 of a resistance welding machine is in contact with one surface 61 of a metal block 60, which is the metal part of the flexible printed wiring board 1, and another surface 62 of the metal block 60 is in contact with a conductor pattern 171 of a rigid substrate 170. Further, a welding tool 92, which is the other welding tool of the resistance welding machine, is in contact with the conductor pattern 171 of the rigid substrate 170. A current can flow in a direction indicated by an arrow in FIG. 6.

In FIG. 7, a welding tool 91 of a resistance welding machine is in contact with one surface 61 of a metal block 60, which is the metal part of the flexible printed wiring board 1, and another surface 62 of the metal block 60 is in contact with a surface 271 of a heat sink. Further, a welding tool 92, which is the other welding tool of the resistance welding machine, is in contact with the surface 271 of the heat sink. A current can flow in a direction indicated by an arrow in FIG. 7.

When a current is caused to flow between the welding tools, heat is generated due to interface resistance between the other surface 62 of the metal block 60 and the metal connection terminal (the conductor pattern 171 of the rigid substrate 170 or the surface 271 of the heat sink), and resistance welding is performed between the other surface 62 of the metal block 60 and the metal connection terminal. As a result, the electronic device in which the other member (the rigid substrate 170 or the heat sink 270) is directly welded to the flexible printed wiring board 1.

Bonding between a flexible substrate and a metal connection terminal may be performed without pulling out a lead wire from the conductor pattern of the flexible substrate. The resistance welding is performed by bringing two electrodes into contact with the metal connection terminal that is connected to the conductor pattern of the flexible substrate and passing a large current. Therefore, this technology is difficult to use when another member that is connected to the flexible substrate has a shape that is not suitable for being in contact with the electrodes.

A flexible printed wiring board according to an embodiment of the present invention has a structure that is weldable to a metal connection terminal of another member.

A flexible printed wiring board according to an embodiment of the present invention includes: a flexible insulating layer; a conductor layer that is formed on at least one surface of the flexible insulating layer; and a metal part that penetrates the flexible insulating layer and the conductor layer. The metal part is formed of a welding base material.

In an electronic device having a flexible printed wiring board according to an embodiment of the present invention, the metal part of a flexible printed wiring board according to an embodiment of the present invention and a metal connection terminal of another member are directly bonded.

A method for manufacturing an electronic device having a flexible printed wiring board according to an embodiment of the present invention includes a process in which a welding tool of a resistance welding machine is brought into contact with one surface of the metal part of a flexible printed wiring board according to an embodiment of the present invention and the other surface of the metal part is directly bonded to a metal connection terminal of another member by resistance welding.

Obviously, numerous modifications and variations of the present invention are possible in light of the above teachings. It is therefore to be understood that within the scope of the appended claims, the invention may be practiced otherwise than as specifically described herein.

1. A flexible printed wiring board, comprising:
a flexible insulating layer;
a conductor layer formed on a surface of the flexible insulating layer; and
a metal block comprising a welding base material and positioned such that the metal block is penetrating through the flexible insulating layer and the conductor layer.

2. A flexible printed wiring board according to claim 1, wherein the welding base material of the metal block is a resist welding base material.

3. A flexible printed wiring board according to claim 1, wherein the metal block has a cross-sectional area in a range of 0.05 mm² to 3.2 mm².

4. A flexible printed wiring board according to claim 1, wherein the metal block is a copper block.

5. A flexible printed wiring board according to claim 2, wherein the metal block has a cross-sectional area in a range of 0.05 mm² to 3.2 mm².

6. A flexible printed wiring board according to claim 2, wherein the metal block is a copper block.

7. A flexible printed wiring board according to claim 3, wherein the metal block is a copper block.

8. A flexible printed wiring board according to claim 5, wherein the metal block is a copper block.

9. A flexible printed wiring board according to claim 1, further comprising:
a second conductor layer formed on a second surface of the flexible substrate,
wherein the metal block is penetrating through the first conductor layer, the flexible substrate, and the second conductor layer.

10. A flexible printed wiring board according to claim 1, wherein the metal block is formed in a plurality such that the plurality of metal blocks is penetrating through the first conductor layer and the flexible substrate.

11. A flexible printed wiring board according to claim 1, further comprising:
a second conductor layer formed on a second surface of the flexible substrate,
wherein the metal block is formed in a plurality such that the plurality of metal blocks is penetrating through the first conductor layer, the flexible substrate, and the second conductor layer.

12. A flexible printed wiring board according to claim 9, wherein the metal block has a cross-sectional area in a range of 0.05 mm² to 3.2 mm².

13. A flexible printed wiring board according to claim 10, wherein the metal block has a cross-sectional area in a range of 0.05 mm² to 3.2 mm².

14. A flexible printed wiring board according to claim 11, wherein the metal block has a cross-sectional area in a range of 0.05 mm² to 3.2 mm².

15. An electronic device, comprising:
the flexible printed wiring board of claim 1;
a structural member having a metal connection terminal such that the metal connection terminal is directly welded to the metal block of the flexible printed wiring board.

16. An electronic device, comprising:
the flexible printed wiring board of claim 1;
a rigid substrate having a conductor pattern such that the conductor pattern is directly welded to the metal block of the flexible printed wiring board.

17. An electronic device, comprising:
the flexible printed wiring board of claim 1;
a heat sink having a surface such that the surface of the heat sink is directly welded to the metal block of the flexible printed wiring board.

18. A method for manufacturing an electronic device, comprising:
preparing a flexible printed wiring board comprising a flexible insulating layer, a conductor layer formed on a surface of the flexible insulating layer, and a metal block comprising a welding base material and positioned such that the metal block is penetrating through the flexible insulating layer and the conductor layer; and
bring a welding tool of a resistance welding machine into contact with a first surface of the metal block in the flexible printed wiring board such that a second surface of the metal block in in the flexible printed wiring board is directly bonded to a metal connection terminal of a structural member by resistance welding.

19. A method for manufacturing an electronic device according to claim 18, wherein the welding base material of the metal block is a resist welding base material.

20. A method for manufacturing an electronic device according to claim 18, wherein the metal block has a cross-sectional area in a range of 0.05 mm² to 3.2 mm².
